(19) United States
(12) Patent Application Publication
(10) Pub. No.: US 2026/0133238 A1
(43) Pub. Date: May 14, 2026

(54) DETECTING CONNECTION ANOMALIES

(71) Applicant: Mellanox Technologies Ltd., Yokneam (IL)

(72) Inventors: Tamar VICLIZKI, Herzliya (IL); Vadim GECHMAN, Kibbutz Hulda (IL); Henning LYSDAL, Roskilde (DK); Shie MANNOR, Haifa (IL)

(73) Assignee: Mellanox Technologies Ltd., Yokneam (IL)

(21) Appl. No.: 19/439,507

(22) Filed: Jan. 5, 2026

Related U.S. Application Data
(63) Continuation-in-part of application No. 17/518,057, filed on Nov. 3, 2021.

(51) Int. Cl. G01R 31/08

(52) U.S. Cl. CPC G01R 31/088

(57) ABSTRACT

A system and method for detecting cable anomalies including collecting a first set cable measurement data, which may be used to create a model including one or more groups based on the collected first set of cable measurement data. A second set of cable measurement data may be collected (e.g. for a specific cable) and a probability of anomaly for cable measurement data of the second set of cable measurement data may be determined, the probability of anomaly based on the deviation of the cable measurement data from one or more groups of the model. Automatic action may be taken, such as isolating the cable.

### RELATED APPLICATION DATA

The present application is a continuation-in-part (CIP) of co-pending U.S. patent application Ser. No. 17/518,057 filed on Nov. 3, 2021, incorporated herein by reference in its entirety.

### FIELD OF THE INVENTION

The present invention relates to systems and methods for analyzing and detecting connection anomalies in cable-based systems, and particularly but not exclusively to systems and methods for predicting failure of a linking component and/or taking action based on a prediction.

### BACKGROUND OF THE INVENTION

Cable or connection reliability and performance is an important and persistent problem in today's large, interconnected society. A significant amount of time and money is spent on analyzing and more importantly, detecting, connection anomalies. Often, it is helpful to discover connection anomalies before they occur or manifest into larger failures affecting critical systems. For example, with time, physical network links suffer from age related degradation resulting in connection instability and performance bottlenecks, reducing bandwidth and increasing packet loss. Perhaps even more problematic is a situation in which an extrinsic force destroys a cable link altogether. For example a submarine communications cable may be snagged by a fishing boat anchor, resulting in a total loss of the link between the connected entities.

### SUMMARY OF THE INVENTION

According to embodiments of the invention, there is provided a system and method for cable anomaly detection and/or cure. Embodiments of the invention may include collecting, by a processor, a first set of cable measurement data; based on the first set of cable measurement data, creating a model which includes one or more groups; collecting a second set of cable measurement data, and for cable measurement data of the second set of cable measurement data, determining a probability of anomaly, wherein the probability of anomaly is based on the deviation of the cable measurement data of the second set of cable measurement data from the one or more groups of the model. Automated action with respect to the cable may be performed. An alert or the probability of anomaly for the cable measurement data of the second set of cable measurement data may be displayed.

According to embodiments of the invention, the model may be a Gaussian mixture model.

Embodiments of the invention may include calculating a deviation, wherein a deviation may be the highest probability of the cable measurement data being part of the one or more groups of the model.

According to embodiments of the invention, there is provided a system and method for cable degradation detection. Embodiments of the invention may include collecting, by a processor, multiple types of cable measurement values. Based on the first set of cable measurement values, creating a model including one or more thresholds. The processor may be to collect a second set of new cable measurement values; and for a new cable measurement value, determining the probability that the cable measurement values follows the distribution of one or more groups of the model; and displaying an alert corresponding to the group associated with the highest probability.

Persons skilled in the art will thus appreciate the need to predict and detect cable or connection failure or anomalies in advance, significantly improving cable link reliability and link performance.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 depicts a high-level block diagram of an exemplary computing device according to some embodiments of the present invention.

FIG. 2 depicts a system for predicting degradation of a cable according to embodiments of the present invention

FIG. 3 depicts a table of example cable threshold behaviors according to embodiments of the present invention.

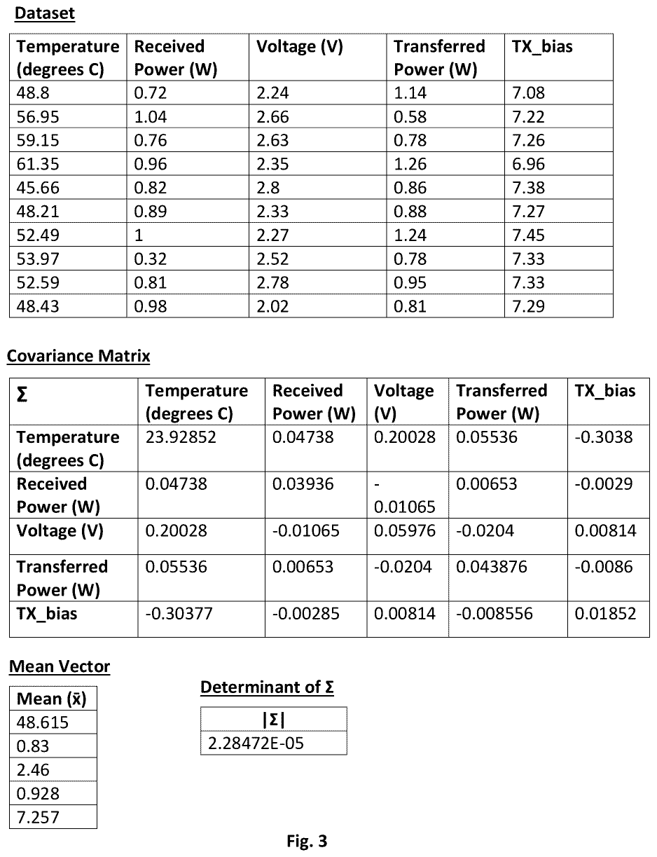

FIG. 4 depicts examples of five types of cable measurement data according to embodiments of the present invention.

FIG. 5 depicts an example diagram of a Gaussian mixture model measuring two types of cable measurement data according to embodiments of the present invention

FIG. 6 depicts an example flow diagram of the cable anomaly detection algorithm according to embodiments of the present invention.

FIG. 7 depicts an example scatter plot of a trend of anomaly analysis algorithm according to embodiments of the invention.

It will be appreciated that for simplicity and clarity of illustration, elements shown in the figures have not necessarily been drawn accurately or to scale. For example, the dimensions of some of the elements may be exaggerated relative to other elements for clarity, or several physical components may be included in one functional block or element. Reference numerals may be repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, and components, modules, units and/or circuits have not been described in detail so as not to obscure the invention. For the sake of clarity, discussion of same or similar features or elements may not be repeated.

Although embodiments of the invention are not limited in this regard, discussions utilizing terms such as, for example, “processing,” “computing,” “calculating,” “determining,” “establishing”, “analyzing”, “checking”, or the like, may refer to operation(s) and/or process(es) of a computer, a computing platform, a computing system, or other electronic computing device, that manipulates and/or transforms data represented as physical (e.g., electronic) quantities within the computer's registers and/or memories into other data similarly represented as physical quantities within the computer's registers and/or memories or other information non-transitory storage medium that may store instructions to perform operations and/or processes. Although embodiments of the invention are not limited in this regard, the terms “plurality” and “a plurality” as used herein may include, for example, “multiple” or “two or more”. The term set when used herein may include one or more items. Unless explicitly stated, the method embodiments described herein are not constrained to a particular order or sequence. Additionally, some of the described method embodiments or elements thereof can occur or be performed simultaneously, at the same point in time, or concurrently.

An embodiment may develop a model of cable measurements, each cable measurement including multiple data points, values or components. The model may include groups, each group having a centroid and corresponding to a status, such as normal, high alarm, low alarm, warning, etc. For a newly received cable measurement including one or more components, that measurement may be compared to the groups to determine a deviation or likely probability that the new measurement conforms to a group: the group having or associated with the highest probability of including the measurement may be chosen as the status and if needed automated action may be taken; an alert with the status may be presented to a user; or other actions may be triggered. An example alert may include the component of the measurement that is most likely to result in the status. That component may be the component with the smallest distance (e.g. Euclidian) from the chosen status or alert group.

Automatic action taken by, for example, a computer system, a controlling computer, or other system, according to embodiments of the invention, may include a remediation protocol or action, for example, targeting the cable subject to the measurement, deviation or probability. Automated action may be executed in response to the determined probability of anomaly (e.g., being higher than a threshold). For example, if a cable is identified as problematic based on a model (e.g. deviation or likely probability is over a threshold), an embodiment may, for example, automatically add the cable to a monitoring watch list for prioritized monitoring; cease (for example, immediately) running client applications over the identified cable or bypass the cable (for example by removing it from an available resource pool to prevent the execution of client applications over the cable); isolate the cable; automatically disconnect the cable; change a data path to avoid the cable; and attempt a re-initialization or restart of the cable or cable link. Following a restart, if subsequent cable measurement data shows no likelihood of anomaly (e.g. conforms to a normal distribution of the model, e.g. a normal group), the cable may be returned to the available resource pool; otherwise, the automated action may include that the cable may be isolated, possibly for manual investigation.

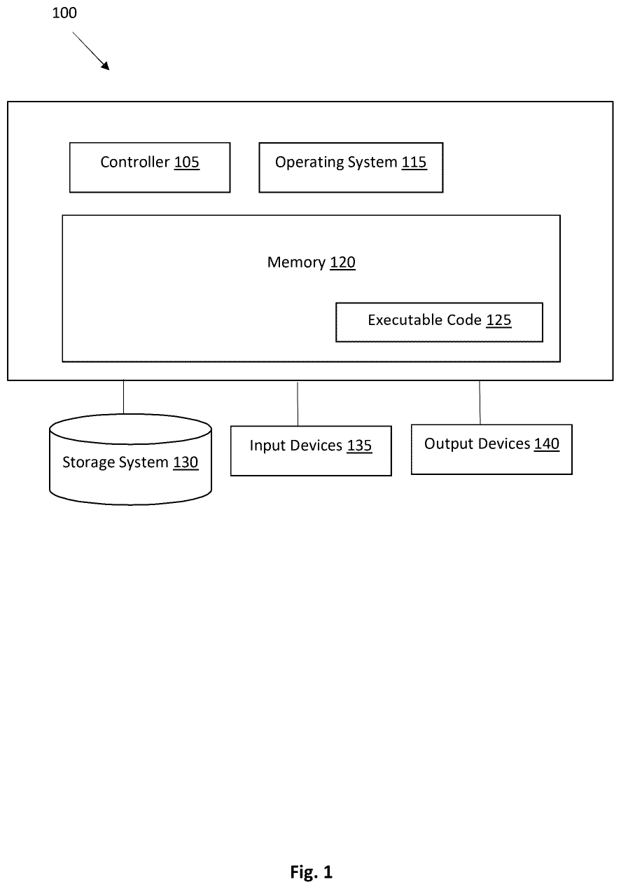

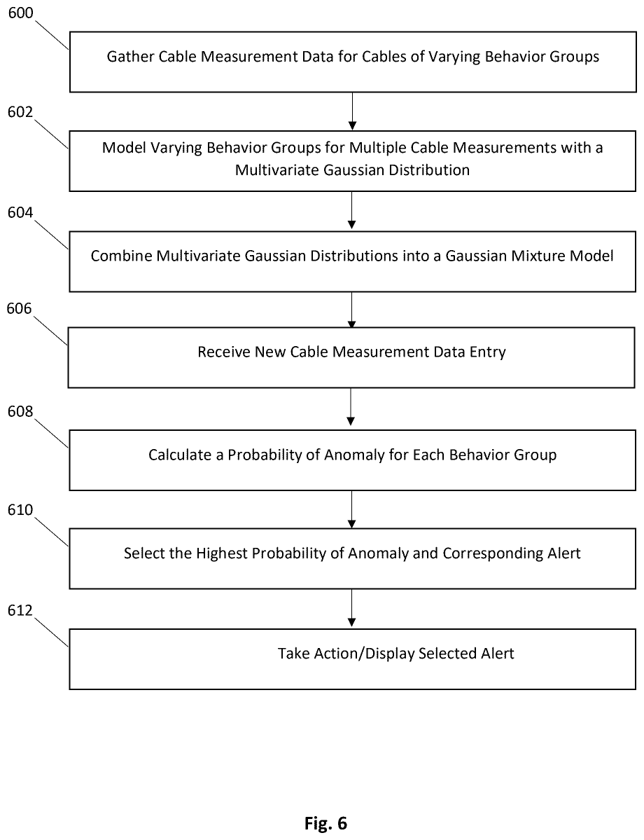

Upon selecting a status associated with an anomaly or alert, a processor or controller (e.g. controller 105, FIG. 1) may initiate an automated mitigation or cure protocol. In one example protocol, the problematic cable may be first registered in a monitoring watch list to track persistent degradation. Simultaneously, an embodiment may remove the cable from an ‘optional pool’ of active hardware resources to ensure that no client applications are executed over the suspected faulty cable or link. A processor or controller may then attempt a recovery sequence, such as a hardware or firmware restart. If a new data entry collected post-restart indicates a return to the ‘normal’ behavior group, the cable may be re-introduced to the optional pool. If the anomaly persists (e.g. if further analysis such as shown in example FIG. 6 shows a probability of anomaly), an embodiment may logically isolate the link and/or trigger an investigation

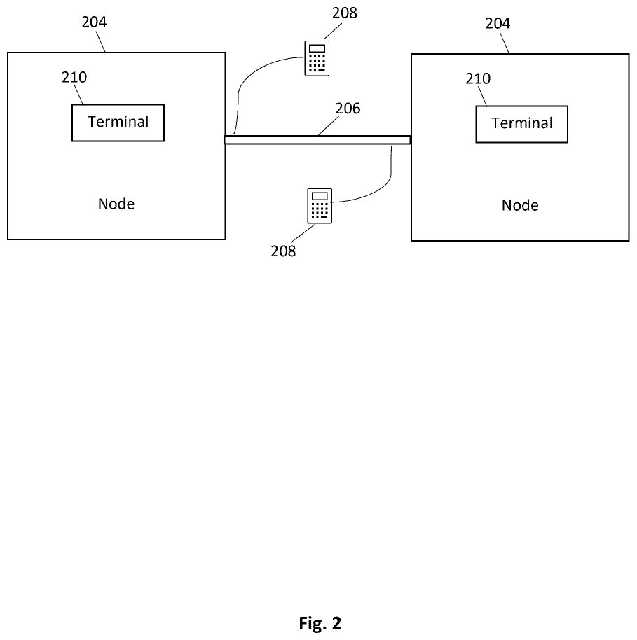

Reference is made to FIG. 1, showing a high-level block diagram of an exemplary computing device according to some embodiments of the present invention. Computing device 100 may include a controller 105 that may be, for example, a central processing unit processor (CPU) or any other suitable multi-purpose or specific processors or controllers, a chip or any suitable computing or computational device, an operating system 115, a memory 120, executable code 125, a storage system 130, input devices 135 and output devices 140. Controller 105 (or one or more controllers or processors, possibly across multiple units or devices) may be configured to carry out methods described herein, and/or to execute or act as the various modules, units, etc. for example when executing code 125. More than one computing device 100 may be included in, and one or more computing devices 100 may be, or act as the components of, a system according to embodiments of the invention. Various components, computers, and modules of FIG. 1 may be or include devices such as computing device 100, and one or more devices such as computing device 100 may carry out functions or be devices such as those described FIG. 2 and produce displays as described herein.

Operating system 115 may be or may include any code segment (e.g., one similar to executable code 125) designed and/or configured to perform tasks involving coordination, scheduling, arbitration, controlling or otherwise managing operation of computing device 100, for example, scheduling execution of software programs or enabling software programs or other modules or units to communicate.

Memory 120 may be or may include, for example, a Random Access Memory (RAM), a read only memory (ROM), a Dynamic RAM (DRAM), a Synchronous DRAM (SD-RAM), a double data rate (DDR) memory chip, a Flash memory, a volatile memory, a non-volatile memory, a cache memory, a buffer, a short term memory unit, a long term memory unit, or other suitable memory or storage units. Memory 120 may be or may include a plurality of, possibly different memory units. Memory 120 may be a computer or processor non-transitory readable medium, or a computer non-transitory storage medium, e.g., a RAM.

Executable code 125 may be any executable code, e.g., an application, a program, a process, task or script. Executable code 125 may be executed by controller 105 possibly under control of operating system 115. For example, executable code 125 may configure controller 105 to calculate and display cable or connection measurement or anomaly data, perform or send commands to perform automated actions (e.g. cable isolation, restart, bypass, etc.), and perform other methods as described herein. A system according to some embodiments of the invention may include executable code 125 that may be loaded into memory 120 or another non-transitory storage medium and cause controller 105, when executing code 125, to carry out methods described herein.

Storage system 130 may be or may include, for example, a hard disk drive, a CD-Recordable (CD-R) drive, a Blu-ray disk (BD), a universal serial bus (USB) device or other suitable removable and/or fixed storage unit. Data such as user data, survey response data, and survey invitations, may be stored in storage system 130 and may be loaded from storage system 130 into memory 120 where it may be processed by controller 105. For example, memory 120 may be a non-volatile memory having the storage capacity of storage system 130. Accordingly, although shown as a separate component, storage system 130 may be embedded or included in memory 120.

Input devices 135 may be or may include a mouse, a keyboard, a microphone, a touch screen or pad or any suitable input device. Any suitable number of input devices may be operatively connected to computing device 100 as shown by block 135. Output devices 140 may include one or more displays or monitors, speakers and/or any other suitable output devices. Any suitable number of output devices may be operatively connected to computing device 100 as shown by block 140. Any applicable input/output (I/O) devices may be connected to computing device 100 as shown by blocks 135 and 140. For example, a wired or wireless network interface card (NIC), a printer, a universal serial bus (USB) device or external hard drive may be included in input devices 135 and/or output devices 140.

In some embodiments, device 100 may include or may be, for example, a personal computer, a desktop computer, a laptop computer, a workstation, a server computer, a network device, or any other suitable computing device. A system as described herein may include one or more devices such as computing device 100

Reference is now made to FIG. 2 depicting a system 200 for predicting or analyzing degradation of a cable or connection according to embodiments of the present invention. Some of the components of FIG. 2 may be separate computing devices such as servers and others may be combined into one computing device. Components and modules of FIG. 2 may be or include computing devices as shown in FIG. 1. In networking, L1 (“layer 1”) describes a well-known term for the 7 layer Open Systems Interconnection (OSI) model in the art of networking describing the physical connection layer in networking. While a specific example network architecture is shown, e.g. using an L1 and other layers, other systems and architectures may be used. The physical layer defines the process of transmitting streams of raw bits or other data over a physical data link which connects network nodes, switch or port 204, typically by a cable or connection 206. A node 204 may be for example, computing device 100 of FIG. 1, or any device capable of receiving and sending data and/or power via cable 206. A node, switch or port, in a network, may be connection point, a redistribution point, or a communications endpoint which may route data or power, usually directed by a device. A node, switch or port 204 may include or be a device capable of collecting, analyzing, processing or displaying received data (e.g. controller 105) e.g. devices such as computers, modems, switches, hubs, bridges, servers, and printers. Nodes 204 may be a computing device capable of displaying, or outputting to a display, information or data related to cable measurements. Cable or connection 206 may be an electrical cable (e.g. made of metal such as copper or steel, with other materials supporting and insulating), a fiber optic cable (e.g. made of plastic or glass, with other layer materials supporting and insulating), or another type of data transmission cable. As the L1 physical may provide the electrical, mechanical, and procedural interface by which streams of raw bits are linked by the transmission medium (e.g. cable), of importance are the electrical and mechanical measurements of the links (e.g. connectors/cable measurements). For example, a cable's voltage, current, and temperature may directly affect a cable's ability to perform adequately and reliably.

Embodiments of the present invention may include collecting or receiving cable measurement data (e.g. receiving, by the processor 105, as in FIG. 1). Cable measurement data may include different measurements attributable to the physical or electrical properties of a cable or connection. Cable measurement data is typically separate from the data sent over the cable: e.g. a cable may transmit bits representing a voice conversation, and those bits are separate from measurements of the physical or electrical properties of the cable. For example, a cable may have physical properties (e.g. electrical properties) measurable by sensors 208, such as, for example: temperature, voltage, current, resistance, power, etc. Other cable features, properties or measurements may be collected. For example, in some embodiments, cable measurement data such as unique identifiers (e.g. cable firmware version, type) and throughput (e.g. speed) may be collected. In many networking applications, fiber optic cables are used, and physical properties such as laser output, laser power, and laser current may be measured. Sensors 208, including, but not limited to, multimeters (e.g. cable testers, oscilloscopes), probes (e.g. temperature probes, infrared temperature sensors, ammeters (e.g. SensorLink's ammeter) may be used to collect cable measurement data.

Cable or connection properties or measurements may be analyzed and input to a model to determine the severity of degradation of a cable. Modeling, as known in the art, may include the mathematical representation of a process, concept, or operation of a system, often built in a computer program. For example, a model may categorize, group, or cluster cable measurement data according to the severity of degradation of a cable. Categorizing cable measurement data may include collecting or receiving data from a degraded or knowingly faulty cable for the purpose of modeling a certain behavior. For example, a degraded power or data cable may have behavior which exhibits low power output due to the resistance of the cable increasing with age. Behaviors may be modeled by thresholds, a mathematical value by which a certain behavior may be categorized (e.g. grouped). A group may contain multiple types of measurements (e.g. multi-dimension) with a distribution about a centroid defined by a threshold value. As an example, for a particular type of cable, the cable measurement data may first be collected for a new cable of that type under normal conditions (e.g. no extrinsic forces, no degradation, a “new” or “ideal” cable) and modeled for its behavior by a defining threshold. In order to model a different threshold behavior, a similar cable (e.g. same type of cable but degraded or faulty) may be used to collect cable measurement data for another threshold. For example, assume that cable measurement data is obtained to categorize a new cable for “normal” behavior and the cable is provided a steady standardized power input of 0.9 mW at one end of the cable, measuring the cable output power at the other end of the cable may exhibit values in the threshold of 0.8-1 mW. To categorize a degraded cable, the same process may be repeated for the same standardized power input and may exhibit values in the threshold of 0.5-0.7 mW. Each type or class of cable may have data collected from it and the data may be respectively modeled for the cable's behavior, each model grouped and classified by a threshold given the known severity of degradation and respective cable measurement data. To provide consistent and accurate data, some embodiments may provide the same input (e.g. same input voltage) and a standard length of cable (e.g. length of new cable=length of faulty cable) to collect cable measurement data such that the collected cable measurement data is standardized.

Cable measurement data may also be generated, to train a model if cable measurement data for a faulty or degraded cable is unavailable. For example, a cable manufacturer may set temperature limits for a cable it manufactures, such that a cable operating at the temperature limit is considered to be at or close to failure. This limit, or values distributed near this limit may be provided to a dataset (e.g. cable measurement data) to train a model for threshold behavior.

In exemplary embodiments, there may be multiple thresholds for each behavior group, each group, besides the normal group, corresponding to a determined level of cable degradation severity. For example, threshold values for a cable temperature measurement may be considered normal (e.g. no degradation) if it falls within the range of 45-55 degrees C. Additionally, tied to the cable degradation severity may be a corresponding alert. For example, multiple thresholds may be related to the severity of the cable degradation may be set to determine whether a warning or an alert is output. As an example, assume a fiber optic cable has cable measurement data which measures the output laser power of the cable given a known input laser power, where the laser output is the method of data is transmission (light as the means of transmission in fiber optics). The cable's output power may be considered normal if the majority of the cable's output power values fluctuates around a threshold of 1.25 mW, given laser input to the cable of 0.9 mW. This value may be considered to be a part of a normal behavior group, as a normal cable exhibiting normal behavior was measured. However, assume for a degraded cable that there may be an unusually high laser light output power given the same laser input, fluctuating around 1.75 mW: this threshold may be considered part of a high behavior group. Conversely, a degraded cable may have unusually low laser output power fluctuating around 0.25 mW: this threshold may be considered part of a low warning/low alarm behavior group. The unusually high or low cable output values may warrant mere warnings. However, in the situation where a cable is severely degraded, a cable's output power may be extremely high, fluctuating around 2.5 mW, this threshold may be a part of the high warning/high alarm alert behavior group, or extremely low, fluctuating around 0.1 mW, part of the low warning/low alarm alert behavior group. At these levels of severe degradation, it may be necessary to provide not only a warning, but an alert. Cable measurement data may therefore be collected for multiple types of data measurements (e.g. temperature, power, etc.) and grouped or clustered according to the severity of degradation (normal, low warning, low alarm, high warning, high alarm, etc.). The severity of degradation or the known thresholds for certain behaviors may be the basis for grouping or clustering cable measurement data.

A Gaussian (e.g. normal) distribution may be used to model cable threshold and normal behavior, according to one embodiment. Returning to the example of the cable above, cable measurement data and it's threshold behavior may follow a Gaussian distribution for each type of cable measurement data (e.g. temperature, power, etc.). For example, in the above example of the fiber optic cable, the laser output power may fluctuate (e.g. vary) around a certain central value (e.g. the expected value or “centroid”) for a behavior group. Therefore, it may be useful to model each type of cable measurement data with a Gaussian distribution. This may be defined as a random variable X for each degradation severity group (e.g. behavior group). For the sake of simplicity, an example is shown in Table 1 for cable measurement data of ‘laser power output’ for 5 similar cables of the same type with different levels of degradation severity.

TABLE 1

| Severity | | Random | | |
|---|---|---|---|---|
| (group) | Notification | Variable | x̅ (in mW) | σ (in mW) |
| Low Alarm | low_alert | X_{lowalert} | 0.1 | 0.1 |
| Low | low_warning | X_{lowwarning} | 0.25 | 0.5 |
| Normal | normal | Xₙₒᵣₘₐₗ | 1.25 | 0.5 |
| High | high_warning | X_{highwarning} | 1.75 | 0.25 |
| High Alarm | high_alert | X_{highalert} | 2.5 | 0.4 |

Each level of degradation may warrant a respective notification as shown in Table 1. For the Gaussian random variable X, the mean x̅ in the example may represent the expected laser power output from cable measurement data for each respective severity, given a specific input. As known in the art, the symbol σ (standard deviation, sometimes variance (σ²) is used) is the value of the measured “spread” (e.g. fluctuations) of the dataset. For example, approximately 1 from the mean accounts for 68% of the sampled data, 2σ accounts for 95% of the sampled data, as known in the art. The values presented in Table 1 are an example and are provided for demonstrative purposes only, however, this data may be obtained from similar cables of the same type with different levels of degradation (e.g. severity of degradation).

Therefore, each random variable X for each level of severity may be defined by a Gaussian distribution for a measurement type. As known in the art, the probability density function for the random variable X, that is P (X=x) is given by f(x) with mean x and standard deviation σ is as shown in example Formula 1.

$$f ( x ) = \frac{1}{σ \sqrt{2 π}} {e}^{- \frac{1}{2} {( \frac{x - μ}{σ} )}^{2}} \qquad Formula 1$$

Although a Gaussian distribution may be used to model (and may be the model) cable measurement data for various degradation severities, this is assuming that only one type of cable measurement data is measured (e.g. only measure laser power output). Expanding the dimension to multiple types of cable measurement data poses a problem. This is due to the dependency of cable measurement data upon each other (e.g. correlation or covariance). For example, higher cable voltages inherently produce more heat (e.g. higher temperature), therefore, there may be a correlation between the two cable measurement data such that modeling each cable measurement data individually would not be adequate. For example, assume for an arbitrary example, that for a cable two different types of cable measurement data are collected, voltage and temperature, the probability for seeing a high voltage is 20% and the probability for seeing a low temperature is 20%. This does not show any form of correlation between the cable measurement data. When combined, it should be evident that the probability of such an event should be extremely low (e.g. an event of high voltage and low temperature), much below 20% (e.g. 4%), indicative of an anomaly.

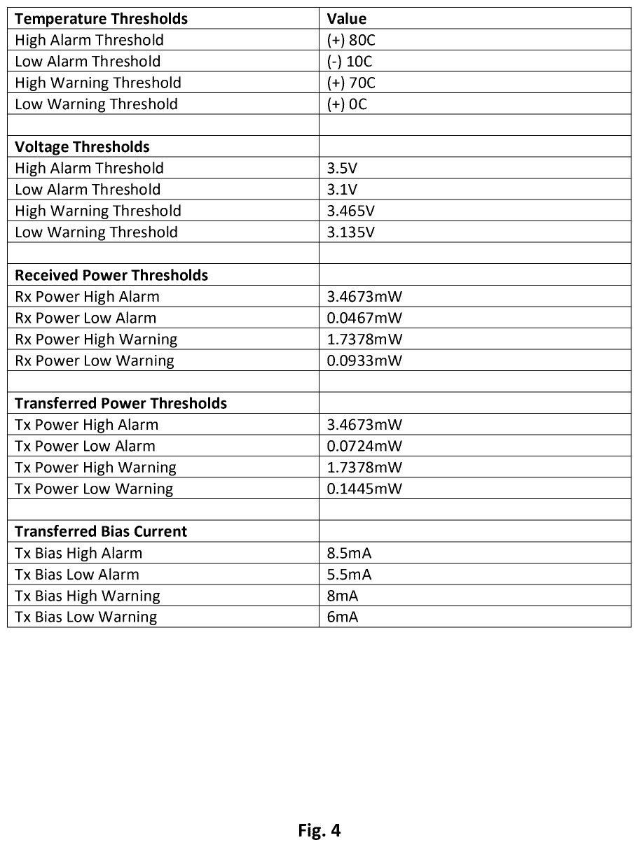

In order to model multiple types of cable measurements together, a multivariate Gaussian distribution may be used. A cable measurement may be a vector including one or more data points, components or values, e.g. an ordered set, where each data point or value is of a specific value such as temperature, power, etc. A set of cable measurement data may include multiple such vectors, each corresponding to a measurement period or point in time. A multivariate Gaussian analysis may vectorize multiple types of cable measurement data, e.g. represented by a matrix where each column is a type of measurement and each row is a sample of multiple measurement. A multivariate Gaussian model may be defined by a random variable X with a p x 1 mean vector x̅ (e.g. p is the number of dimensions) and a p x p covariance matrix Σ. As known in the art, the joint density function for a multivariate random variable X, that is, the probability of an input vector x̅ (e.g. p x 1) is given by φ(x) in example Formula 2 below:

$$ϕ ( x ) = {( \frac{1}{2 π} )}^{p / 2} {\vert \sum \vert}^{- 1 / 2} exp \{ - \frac{1}{2} {( x - μ )}^{′} {\sum }^{- 1} ( x - μ ) \} \qquad Formula 2$$

Where for p types of cable measurement data, the probability of a vector x (e.g. probability that the set of cable measurement data takes on the values of input row vector x) is given by the above Formula 2. The mean vector x̅ contains the mean value for each type (e.g. component of the vector) of cable measurement data and |Σ| denotes the determinant of the covariance matrix. Σ⁻¹ is the inverse of the covariance matrix and (x-x̅)′ is the transpose of the row vector x subtracted from the mean vector x. Turning to FIG. 4, an illustrative example of five types of cable measurement data is shown according to embodiments of the present invention. For example; temperature, received power, voltage, transferred power, and tx_bias were each measured for 10 samples (e.g. sample periods). The covariance matrix Σ and mean vector x̅ may be computed by functions (e.g. Excel's COVARIANCE and AVERAGE functions). A corresponding covariance matrix Σ was calculated as well as the determinant of the matrix. Therefore, for any row vector x, the probability may be calculated by applying Formula 2 given the covariance matrix Σ and mean x̅.

Given this, the probability for any set of cable measurement data may be mapped. For example, for an N=1,000 sample of p-5 types of cable measurement data (e.g. each row vector having length 5, 1,000×5 matrix), the probability density function may be mapped for each sample (e.g. row vector) of the 1,000 samples to a probability using Formula 2. For example, a new data entry may be retrieved in row vector form (e.g. each column a separate type of measurement) and a probability calculated for each behavior group using Formula 2 above.

To complete the model, cable measurement data may be obtained from similar cables of the same type with different levels of degradation, each level of degradation representing a behavior group and modeled by a separate multivariate Gaussian distribution (e.g. each with a mean vector and a covariance matrix). For each behavior group, for each cable measurement type, an expected value may be calculated each expected value combined into a mean vector x, or called the “centroid”. The centroid indicates the point at which the probability for the multivariate distribution that is part of the group which has the centroid point is the highest. In some embodiments, the probability that a measurement or a set of measurements is associated with a certain group and thus associated with a certain alarm or anomaly may be based on the deviation or distance of that set of measurements to the centroid of a group associated with that anomaly or alarm. The deviation from a group may be measured by deviation from the center of the group.

To further compact this model, in some embodiments, a multivariate Gaussian distribution may model each group, cluster, or level of degradation as one distribution. As such, with multiple independent multivariate Gaussian distributions, the distributions may be combined into a single distribution for efficient analysis. The multiple behavior groups each modeled by a multivariate Gaussian distributions may be combined into what is known in the art as a Gaussian mixture model (GMM) where the multiple multivariate Gaussian distributions are “averaged”. In other words, “averaged” refers to the total probability not exceeding 100%, therefore the mathematical integral of the GMM model should equal 1. Methods of grouping cable data other than GMM may be used, for example clustering algorithms may be used.

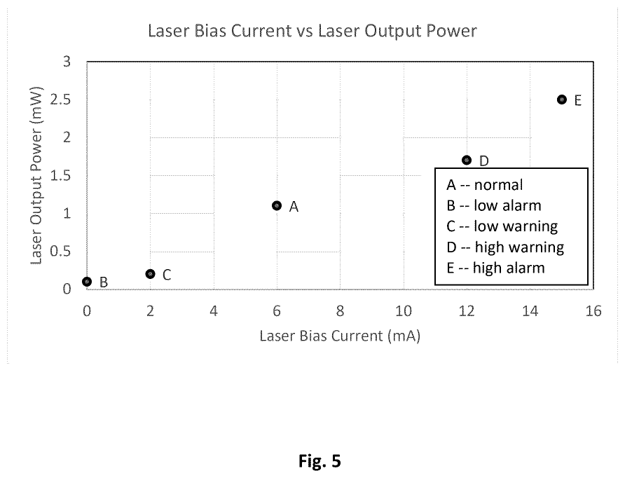

Reference is now made to FIG. 5, which is an example diagram of a Gaussian mixture model measuring two types of cable measurement data according to embodiments of the present invention. The two types of cable measurement data, laser output power and laser bias current, are visibly shown in FIG. 5 with 5 different centroids, each centroid related to a behavior group determined by a multivariate Gaussian model. Each centroid may have been modeled by using threshold values or measured from cables with varying levels of degradation. As shown, a normal “ideal” cable without degradation is shown at point A as having an expected value (e.g. mean) of laser bias current of 6 mA and laser output power of 1.1 mW, determined by a multivariate Gaussian model. As shown at point B, a cable which exhibits laser bias current of 0 mA and a laser output power of 0.1 mW was modeled by a severely degraded cable, part of the “low alarm” behavior group. For each new data entry (e.g. a row vector), the vector may be applied to the GMM in order to select the closest centroid to the new data entry (e.g. highest probability). Each multivariate Gaussian mixture model (e.g. related to each centroid) may have a corresponding covariance matrix E and mean x to calculate the probability according to Formula 2. The closest centroid corresponds to an alert which may be given to a user. For example, assume a new data entry indicates a laser bias current of 0.1 mA and a laser power output of 0.1 mW. According to FIG. 5, this may indicate a low_alarm as this new data entry value is nearest to the B centroid, but this does not account for variance. Therefore, calculation of a Euclidean distance (e.g. distance from new data entry to a centroid) is not enough to calculate the “closest” centroid. For example, for more ambiguous datapoints, for example a laser bias current of 1 and laser output power of 0.1, it may be more difficult to determine which centroid, B or C, this new data entry falls to. Therefore, to calculate a new data entry's deviation or distance from any of the centroids, a probability based approach may be used. An embodiment may calculate probabilities using a GMM solution to select the centroid based on the probability of the new data entry applied to each multivariate Gaussian distribution of each respective behavior group (e.g. centroid). Therefore, for each new data entry, the probability that the new data entry lies within the multivariate distribution of each respective centroid may be calculated, e.g. according to Formula 2 above. The multivariate Gaussian distribution or group which results in or is associated with the highest probability (e.g. least deviation from the centroid), may be the behavior group selected. The likelihood of the new data entry following the distribution of a behavior group may be considered as the deviation. The classification of a new entry (e.g. new data corresponding to a cable being analyzed) as potentially faulty may be determined by its probability and proximity to a cluster previously identified as problematic regarding cable performance. Data, result or an alert returned may be a probability score and a system may adjust a decision threshold for flagging cables as ‘faulty’ based on the context for a particular use-case, or user configurations.

In some embodiments, the normal behavior group may be used to calculate a Euclidean distance between the new data entry and the centroid of the normal behavior group. The calculation of the Euclidean distance may indicate which measurement type (e.g. voltage, temperature, laser power, etc.) most significantly affected a cable's behavior from normal. For example, assume a cable measures two cable measurements, voltage and power. Further assume that the retrieved cable data for this cable is distributed around a centroid located at and with the values of: voltage=1V and power=1 mW. A new data entry may be retrieved and may have values such as: voltage=2V and power=3 mW. To calculate the Euclidean distance for each measurement type, the absolute value of the difference between the new data entry and the normal centroid may be calculated, resulting in a Euclidean distance of 1V for voltage (2V-1V) and 2 mW for power (3 mW-1 mW). The cable measurement type which resulted in the largest ratio of change may be indicated as the cable measurement which most affected cable behavior from normal. The largest ratio of change may be, for example, the most influential, “influencer” cable measurement. For example, in the above example there is a 100% ratio of change (2-1/1) for voltage and a 200% ratio of change (3-1/1) for power. Therefore, power was more impactful in this new data entry when compared to voltage. This may provide insight to an analysis, as an increase in power with a disproportionate increase in voltage as exampled may indicate that the conductivity of a cable is increasing (e.g. higher power should be balanced by the voltage squared P=V²/R, if all else equal).

Reference is now made to FIG. 6, which is an example flow diagram of the cable anomaly detection algorithm according to embodiments of the present invention. In operation 600 a set of cable measurement data is gathered for multiple cables of varying degradation. Embodiments of the invention may receive cable measurement data and may actively log or archive (e.g. xls format, csv format, or other formats) the gathered cable measurement data. For example, cable measurement data may be continuously received and updated real-time from a variety of sensors monitoring cable properties or parameters (e.g. voltage, power, current). A large amount of cable measurement data may be collected, (e.g. in some implementations cable measurement data may be collected every second, across many users, sensors, devices). Cable measurement data may be gathered for multiple types of cable measurements (e.g. voltage temperature, current) at a variety of different times or set periods (e.g. once a week, every minute). Cable measurement data may be collected for cables with different levels of degradation (e.g. degraded, faulty) and the collected data may then be grouped accordingly by degradation level. Before collecting cable measurements, knowingly faulty cables may be sized and lengthened accordingly to match a degraded cable in order to ensure consistency across cable measurements. The cable measurement data gathering process may be repeated to model each cable of differing degradation.

At the completion of the data gathering process, at operation 602, a multivariate Gaussian distribution may be used to model each behavior group of cable measurement data for multiple types of cable measurement data. For example, give types of cable measurements may be collected repeatedly for the same type of cable for varying levels of degradation. The set of cable measurement data may be represented for example by a matrix, with each row vector defining each entry of cable measurement data. The multivariate Gaussian model allows for the determination of a mean vector and the covariance matrix, with the mean vector defining the centroid of each respective behavior group and covariance defining the correlation between the groups.

At operation 604, the multivariate Gaussian models may be averaged and combined into one Gaussian mixture model. The calculated centroids determined in operation 602 may therefore be mapped on the Gaussian mixture model.

At operation 606, a new cable measurement data entry may be received. For example, a new data entry may be a row vector specifying the exact values of 5 different types of cable measurement data specified (see FIG. 4). For example, a new data entry may include a row vector: temperature=55 degrees C., received power=1 mW, voltage=2.2V, transferred power=0.95 mW, bias current=7.2 mA. The new cable measurement data entry (e.g. a second set of data) may be with respect to, associated with or describing a specific cable being analyzed. The relevant cable being analyzed may be identified by its serial number.

In order to apply the Gaussian mixture model created at operation 604, a probability of anomaly, or the alert, behavior or classification given by a certain group, may be calculated at operation 608. In operation 608, a process may select one of the behavior groups based on the deviation of the new data entry from each of the behavior groups. For example, the probability of anomaly that the new data entry is in each of the low alarm behavior group, low behavior group, normal group, high behavior group, or high alarm behavior group may be respectively calculated. To select the group, the value of the multivariate Gaussian components of the Gaussian mixture model (e.g. related to each centroid) which provides the highest probability e.g. according to Formula 2, hence the smallest deviation for the new data entry, e.g. the group centroid of which the new data entry is “closest” to, may be selected as the behavior group.

A model such as a GMM may represent the data. Instead of assuming the data follows one simple distribution, the GMM assumes the data is composed of multiple sub-populations (e.g., groups). Such a model may be, e.g. multivariate, such that the model considers multiple variables (e.g. features) simultaneously (e.g., cable voltage, temperature, signal-to-noise ratio, etc.) rather than just one. Each “group” or cluster in the model may be defined by a Gaussian (e.g. normal) distribution, characterized by its own mean (e.g. centroid) and covariance (e.g., spread). A selection mechanism may use the highest probability. A new, unseen data entry (e.g. from a cable being analyzed) may be assigned to a specific behavior group. When a new data entry for a cable being analyzed is received, an embodiment may evaluate it against every Gaussian component in the model. For each component, a probability value may be calculated (e.g., as in Formula 2). This value may represent the likelihood that the data entry belongs to that specific component. An embodiment may select the component that yields the highest probability score. In statistical terms, this is often referred to as a “Maximum Likelihood” assignment. A metric of “closeness” may be the smallest deviation. A new data group having the “highest probability” of having an anomaly may be mathematically to equivalent it having the “smallest deviation” from a centroid. Each behavior group may have a “centroid”, e.g., the multi-dimensional center of that group's distribution. The “Closest” group to a new data point may be that having the lowest distance such as the Euclidean (multi dimention) distance, e.g. the smallest Mahalanobis distance or other similar metric, from a centroid having a high probability of anomaly; e.g. a measurement which measures how many standard deviations the new data point is from the centroid, accounting for the shape and orientation of the cluster. A new data point corresponding to a cable may be mapped to the group whose characteristics most closely align with its own, minimizing the statistical error of the classification. Such a process may categorize the new data into a “behavior group.” For cable performance, an embodiment may compare a new cable's current metrics against the “learned” signatures of known healthy cables vs. known faulty cables. If the new data shows the “smallest deviation” from the “Faulty Group” centroid, it may be classified as suspicious.

In operation 610, the group that was selected in operation 608 may be analyzed against the individual components or values of the new data entry to find the individual component or value that results in the alarm. For example, if the high alarm group is selected, each of the components of the new data entry may have its distance (e.g. Euclidian distance, or another distance measure) compared against that matching (e.g. measuring the same unit) component of the chosen group's centroid, and the new data entry having the furthest distance from the centroid may be selected. Thus if the new data entry results in the “power” component being further from the centroid of the high alarm group than any other component (e.g. temperature, etc.), the alarm may be “high alarm, power”.

At operation 612, automated action may be taken (e.g. with respect to the cable associated with the new or second set of cable measurements), and/or an alert may be given or displayed based on the selected group. For example, in conjunction with or instead of the display of an alert, a system (e.g. controller 105) may for example, isolate the cable, cease running applications over the cable or bypass traffic over the cable, or perform other actions. The cables having action taken with respect to them may be identified by their serial numbers. For example, a process may take automated action by performing a sequence of state-management actions such as: Watch List Integration, where the cable is flagged (e.g. in the storage system 130) for continuous observation; Traffic Redirection, where the system updates the resource availability to exclude the cable from the optional pool, preventing client application traffic; Re-initialization, where a restart command is automatically issued to the cable or its associated node (e.g. node 204); Conditional Re-integration, where the system evaluates post-restart measurement data against a model such as a GMM (e.g. as in operations 606-610). In one embodiment, if the re-calculated probability of anomaly falls below a threshold, the cable is returned to the pool; otherwise, it may be automatically isolated (e.g. for investigation). If the new data entry is closest to the centroid of the low behavior group (e.g. highest probability that the new data entry falls within this low group), a low warning may be given.

While certain categories of alarms, e.g. normal, low alarm, etc., are discussed herein, other or different categories or groups may be used. Alerts may be displayed, for example on a computing device, such as a user terminal 210 alongside vital information related to the cable measurement data. Alerts may be used to notify a user real time or displayed to software program based on received cable measurement data. Terminals 210 may be units separate from nodes 204.

Other or different operations may be used.

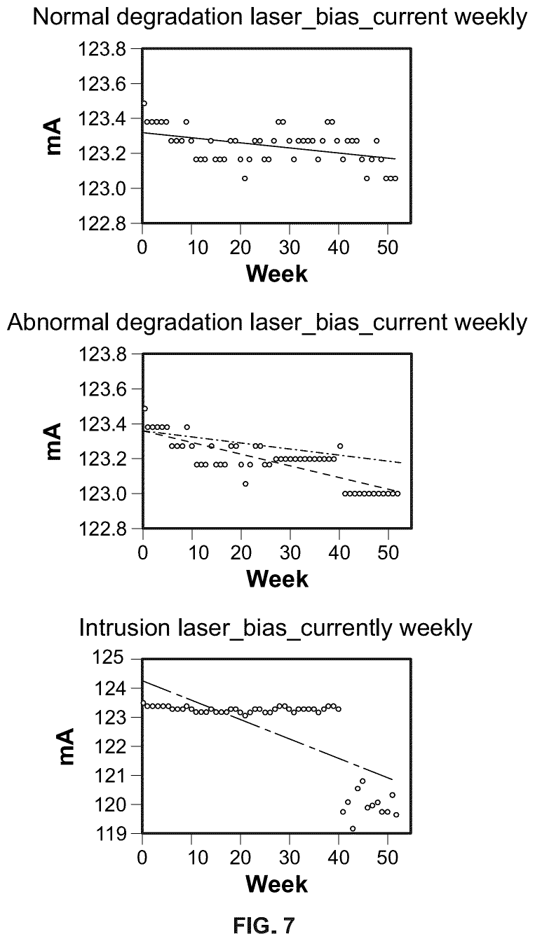

Reference is now made to FIG. 7, which is an example scatter plot of the trend of anomaly analysis algorithm according to embodiments of the invention. Embodiments of the invention may analyze cable measurement data to predict anomaly trends which indicate degradation, intrusion, and any abnormal behavior of cables. The data may be analyzed to create a model which may provide a general trend of degradation, the speed of degradation, or abnormal trends. In one embodiment, during a set period of time, cable measurement data may be gathered or received (e.g. processor 105) from multiple sources (e.g. multiple sensors (e.g. sensors 208), multiple computers connected to multiple sensors, external third-party sources); however the data analysis discussed herein may be performed at a user terminal. At for example a central server which receives sensor data from multiple user terminals, the cable measurement data may be used to create, use and update the model.

An embodiment may create and aggregate past cable measurement data to recently retrieved cable measurement data to calculate a linear regression line for a model. For example, cable measurement data for cable voltage may be periodically retrieved from a sensor 208. To determine a linear regression, a least squares technique may be implemented on each data point to calculate a line of best fit to determine a slope m. As known in the art, the regression line, also known as “line of best fit” may be modeled by the function y (x) with input x given by example Formula 3 below:

y(x)=m*x+b Formula 3

The letter b in Formula 3 denotes a constant where the line of best fit intersects the y-axis, e.g. when x=0. Of importance is the slope of the line denoted by m which may be monitored over time for a rate of change of slope. The slope of the line as known in the art is the change in the value of y divided by the change in the value of x, this value is a constant value for a linear regression.

To apply the linear regression model, upon each new data entry, the distance of the new data entry from the line of best fit may be determined. When analyzing the new data entry, the further the distance from the line of best fit, the more this value may indicate a trend of anomaly. In one embodiment, to determine the distance, the time of the new data entry may be used to calculate the value of the function compared to the value of the determined line of best fit at the same time. The calculated value from the line of best fit may be subtracted from the new data entry value for the difference. A positive value indicates an upward trend whereas a negative value indicates a downward trend, an equivalent value indicates no trend. As an example, assume for a future time t=1, the value of cable measurement data for voltage is 5V. Additionally, assume a linear regression was modeled for previous voltage cable measurement data by a least squares method and a line of best fit was determined, given by the equation y=3x+4. According to this simple model, the model projects that the value calculates to 7 (e.g. 3*1+4) if it follows the linear regression of past voltage data. However, the new data entry indicates 5V, showing a much lower value than expected. Subtracting the values accordingly results in a distance of −2V (e.g. 5-7), indicating an immediate negative trend with a magnitude of 2V.

In some embodiments, past cable measurement data may be modeled by a Gaussian distribution. For the value of each new data entry, the value may be compared to the modeled Gaussian distribution of past cable measurement data. A threshold may be implemented where any new data entry beyond a standard value requires an alert requires an alert. As an example, assume that cable voltage was measured and a Gaussian distribution modeled with a sample mean of 5 mV and a standard deviation (σ) of 2 mV was calculated. If, for example, a threshold for alert was set at 3 standard deviations (3σ). Any new data entry value beyond 11 mV (5+(2*3)) or below −1 mV (5−(2*3)) would be candidates for alert. This threshold may be set by the user.

Additionally, aggregating the new data entry to the set of modeled cable measurement data may change the slope of the original linear regression line. The rate of this change of slope may be determined. In order to determine a rate of degradation, some embodiments may collect new data entries during a set period of time and may examine the rate of the change of slope from period to period. For example, new data may be collected on a weekly basis and a new linear regression model calculated for the slope m. The change of the slope from week to week, also known in the art as the acceleration or second derivative m′ may be calculated. The higher the value of the second derivative m′ over time, the faster the rate of degradation. The general trend of anomaly may be indicated by the sign of m′, a positive m′ indicates an upward trend whereas a negative m′ indicates a downward trend. As the distance may provide the magnitude of change of the trend of anomaly, the rate of change of slope provides the rate or speed at which this change may be occurring.

Descriptions of embodiments of the invention in the present application are provided by way of example and are not intended to limit the scope of the invention. The described embodiments comprise different features, not all of which are required in all embodiments. Embodiments comprising different combinations of features noted in the described embodiments, will occur to a person having ordinary skill in the art. Some elements described with respect to one embodiment may be combined with features or elements described with respect to other embodiments. The scope of the invention is limited only by the claims.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

1. A method for cable anomaly detection, the method comprising, using a computer operating a processor:
collecting a first set of cable measurement data;
based on the first set of cable measurement data, creating a model including a plurality of groups;
collecting a second set of cable measurement data associated with a cable;
for cable measurement data of the second set of cable measurement data, determining a probability of anomaly, wherein the probability of anomaly is based on the deviation of the cable measurement data of the second set of cable measurement data from one or more groups of the model; and
based on the probability of anomaly for the cable measurement data of the second set of cable measurement data, performing automated action with respect to the cable.

2. The method of claim 1, wherein the deviation is the highest probability of the cable measurement data being part of the groups of the model.

3. The method of claim 1, wherein the model is a gaussian mixture model.

4. The method of claim 1, wherein for cable measurement data of the second set of cable measurement data, a Euclidean distance is calculated between a centroid of a normal group and the cable measurement data.

5. The method of claim 4, wherein the automatic action is selected from the group consisting of: adding the cable to a monitoring watch list; removing the cable from an available resource pool; performing a restart of the cable; and isolating the cable.

6. The method of claim 1, comprising determining a trend of anomaly, wherein the trend of anomaly is the linear regression change of slope of cable measurement data over time.

7. The method of claim 1, wherein the cable is a fiber optic cable.

8. The method of claim 1, wherein the cable measurement data measures at least one of: unique identifier, throughput, laser output, laser power, and laser current.

9. The method of claim 1, comprising determining the group associated with the highest probability of including cable measurement data of the second set of cable measurement data and using the determination to determine the probability of anomaly by the determining of a probability of anomaly.

10. A system for cable anomaly detection, the system comprising:
a memory;
a processor to:
collect a first set of cable measurement data;
based on the first set of cable measurement data, create a model including a plurality of groups;
collect a second set of cable measurement data associated with a cable;
for cable measurement data of the second set of cable measurement data, determine a probability of anomaly, wherein the probability of anomaly is based on the deviation of the cable measurement data of the second set of cable measurement data from one or more groups of the model; and
based on the probability of anomaly for the cable measurement data of the second set of cable measurement data, performing automated action with respect to the cable.

11. The system of claim 10, wherein the deviation is the highest probability of the cable measurement data being part of the groups of the model.

12. The system of claim 10, wherein the model is a Gaussian mixture model.

13. The system of claim 10, wherein for cable measurement data of the second set of cable measurement data, a Euclidean distance is calculated between a centroid of a normal group and the cable measurement data.

14. The system of claim 13, wherein the automatic action is selected from the group consisting of: adding the cable to a monitoring watch list; removing the cable from an available resource pool; performing a restart of the cable; and isolating the cable.

15. The system of claim 10, wherein the processor is to determine a trend of anomaly, wherein the trend of anomaly is the linear regression change of slope of cable measurement data over time.

16. The system of claim 10, wherein the cable is a fiber optic cable.

17. The system of claim 10, wherein the cable measurement data measures at least one of: cable unique identifier, throughput, laser output, laser power, and laser current.

18. The system of claim 10, wherein the processor is to determine the group associated with the highest probability of including cable measurement data of the second set of cable measurement data and use the determination to determine the probability of anomaly by the determining of a probability of anomaly.

19. A method for cable degradation detection, the method comprising, using a computer operating a processor:
collecting a first set of multiple types of cable measurement values;
based on the first set of cable measurement values, creating a model including a plurality of more thresholds;
collecting a set of new cable measurement values associated with a cable;
for a new cable measurement value, determining the probability that the cable measurement value follows the distribution of one or more groups of the model; and
based on the group associated with the highest probability, performing automated action with respect to the cable.

20. The method of claim 19, wherein the model is a Gaussian mixture model.
